(19) United States
(12) Patent Application Publication
(10) Pub. No.: US 2024/0160095 A1
(43) Pub. Date: May 16, 2024

(54) REFLECTION-TYPE MASK BLANK, REFLECTION-TYPE MASK, METHOD FOR MANUFACTURING REFLECTION-TYPE MASK, AND METHOD FOR MANUFACTURING SEMICONDUCTOR DEVICE

(71) Applicant: HOYA CORPORATION, Tokyo (JP)

(72) Inventor: Masanori NAKAGAWA, Tokyo (JP)

(73) Assignee: HOYA CORPORATION, Tokyo (JP)

(21) Appl. No.: 18/282,483

(22) PCT Filed: Mar. 24, 2022
(86) PCT No.: PCT/JP2022/014156

§ 371 Date: Sep. 15, 2023

(30) Foreign Application Priority Data
Mar. 26, 2021 (JP) 2021-053450

(51) Int. Cl. G03F 1/24

(52) U.S. Cl. CPC G03F 1/24

(57) ABSTRACT

Provided are a reflective mask blank, a reflective mask, a method for manufacturing a reflective mask, and a method for manufacturing a semiconductor device, capable of suppressing occurrence of a blister of a substrate edge portion under an EUV exposure environment in a hydrogen atmosphere.

The reflective mask blank comprises a substrate, a multilayer reflective film on the substrate, a protective film on the multilayer reflective film, and an absorber film on the protective film. When the film thickness of the absorber film at a center of the substrate is T nm, there is at least one location where the film thickness of the absorber film in a range of 2.5 mm or less from a side surface of the substrate toward the center thereof is the smaller of 35 nm or less or (T−5) nm or less.

### CROSS-REFERENCE TO RELATED APPLICATIONS

This application is the National Stage of International Application No. PCT/JP2022/014156, filed Mar. 24, 2022, which claims priority to Japanese Patent Application No. 2021-053450, filed Mar. 26, 2021, and the contents of which is incorporated by reference.

### TECHNICAL FIELD

The present disclosure relates to a reflective mask blank, a reflective mask, a method for manufacturing a reflective mask, and a method for manufacturing a semiconductor device.

### BACKGROUND ART

With a further demand for higher density and higher accuracy of a VLSI device in recent years, extreme ultraviolet (hereinafter referred to as “EUV”) lithography, which is an exposure technique using EUV light, is promising. The EUV light refers to light in a wavelength band of a soft X-ray region or a vacuum ultraviolet region, and is specifically light having a wavelength of about 0.2 to 100 nm.

A reflective mask used in the EUV lithography includes a multilayer reflective film for reflecting exposure light, formed on a substrate, and an absorber pattern which is a patterned absorber film for absorbing exposure light, formed on the multilayer reflective film. EUV light incident on the reflective mask mounted on an exposure apparatus for performing pattern transfer onto a semiconductor substrate is absorbed in a portion having an absorber pattern, and is reflected by the multilayer reflective film in a portion having no absorber pattern. A light image reflected by the multilayer reflective film is transferred onto a semiconductor substrate such as a silicon wafer through a reflective optical system, and a desired circuit pattern can be thereby formed.

For example, Patent Document 1 discloses a reflective mask blank in which a multilayer reflective film that reflects EUV light, a protective film for protecting the multilayer reflective film, an absorber film that absorbs EUV light, and a resist film are sequentially formed on a substrate, in which when a distance from a center of the substrate to an outer peripheral end of the multilayer reflective film is denoted by L (ML), a distance from the center of the substrate to an outer peripheral end of the protective film is denoted by L (Cap), a distance from the center of the substrate to an outer peripheral end of the absorber film is denoted by L (Abs), and a distance from the center of the substrate to an outer peripheral end of the resist film is denoted by L (Res), L (Abs)>L (Res)>L (Cap)>L (ML) is satisfied, and the outer peripheral end of the resist film is closer to a center side than an outer peripheral end of the substrate.

For example, Patent Document 2 discloses an exposure reflective mask blank including a substrate, a multilayer reflective film that is sequentially formed on the substrate and reflects exposure light, and an absorption film that absorbs exposure light, in which the multilayer reflective film is formed by alternately building up a heavy element material film and a light element material film having different refractive indexes, and the exposure reflective mask blank includes a protective layer that protects at least a peripheral end portion of the heavy element material film in the multilayer reflective film. In addition, Patent Document 2 describes that an absorption film is formed in a film forming region larger than a film forming region of the multilayer reflective film.

### PRIOR ART DOCUMENTS

### Patent Documents

Patent Document 1: WO 2014/021235 A
Patent Document 2: JP 2003-257824 A

### SUMMARY OF DISCLOSURE

### Technical Problem

As described above, the reflective mask blank has a structure in which a multilayer reflective film, a protective film, an absorber film, and the like are layered on a substrate. When a reflective mask is manufactured, first, a resist film for electron beam drawing is formed on a surface of the reflective mask blank. Next, a desired pattern is drawn on the resist film with an electron beam, and the pattern is developed to form a resist pattern. Next, using the resist pattern as a mask, the absorber film is dry-etched to form an absorber pattern (transfer pattern). As a result, it is possible to manufacture a reflective mask in which the absorber pattern is formed on the multilayer reflective film.

By the way, in an EUV exposure apparatus that transfers an integrated circuit pattern onto a semiconductor substrate by EUV light reflected by a reflective mask, since EUV light is strongly absorbed by gas molecules, it is generally necessary to keep the inside of an optical system container at a high vacuum. However, impurities such as moisture and a hydrocarbon cannot be completely eliminated even in high vacuum, and when these impurities are exposed to EUV light, a carbon film or the like is deposited on a mirror surface, resulting in a decrease in reflectance. In the EUV exposure apparatus, exposure in a hydrogen atmosphere having high EUV light transmittance is performed in order to suppress such contamination.

However, when the reflective mask is irradiated with EUV light, a blister-like defect (hereinafter, referred to as “blister”) may occur at a part of an interface between a glass substrate and a film formed on a surface of the glass substrate. When film peeling caused by such a blister scatters on a multilayer reflective film, an absorber film, or the like, a fatal defect that affects EUV exposure occurs, and there arises a problem that use as a reflective mask is impossible. As main factors of occurrence of such a blister, hydrogen decomposed by EUV light is taken into the layered film, a hydrogen internal pressure increases at a specific film interface, and a film stress applies a load to the interface having a high hydrogen internal pressure.

The present disclosure has been made in order to solve the above-described problems, and an aspect of the present disclosure is to provide a reflective mask blank, a reflective mask, a method for manufacturing a reflective mask, and a method for manufacturing a semiconductor device, capable of suppressing occurrence of a blister at a substrate edge portion under an EUV exposure environment in a hydrogen atmosphere.

### Solution to Problem

In order to solve the above problems, the present disclosure has the following configurations.

(Configuration 1) A reflective mask blank comprising: a substrate; a multilayer reflective film on the substrate; a protective film on the multilayer reflective film; and an absorber film on the protective film, in which when the film thickness of the absorber film at a center of the substrate is T nm, there is at least one location where the film thickness of the absorber film in a range of 2.5 mm or less from a side surface of the substrate toward the center thereof is the smaller of 35 nm or less or (T−5) nm or less.

(Configuration 2) The reflective mask blank according to configuration 1, in which when a distance from the center of the substrate to an outer peripheral end of the multilayer reflective film is denoted by Lml, and a distance from the center of the substrate to an outer peripheral end of the protective film is denoted by Lcap, Lml<Lcap is satisfied, and there is at least one location where the total film thickness of the protective film and the absorber film in the range of 2.5 mm or less from the side surface of the substrate toward the center thereof is 4.5 nm or more.

(Configuration 3) The reflective mask blank according to configuration 1 or 2, in which the absorber film comprises at least one selected from tantalum (Ta), palladium (Pd), zirconium (Zr), hafnium (Hf), yttrium (Y), niobium (Nb), vanadium (V), titanium (Ti), lanthanum (La), and scandium (Sc).

(Configuration 4) The reflective mask blank according to any one of configurations 1 to 3, in which the film thickness T nm of the absorber film at the center of the substrate is 30 nm or more.

(Configuration 5) The reflective mask blank according to any one of configurations 1 to 4, in which the protective film comprises ruthenium (Ru).

(Configuration 6) A reflective mask comprising an absorber pattern in which the absorber film in the reflective mask blank according to any one of configurations 1 to 5 is patterned.

(Configuration 7) A method for manufacturing a semiconductor device, the method comprising setting the reflective mask according to configuration 6 in an exposure apparatus comprising an exposure generation unit that generates EUV light and transferring a transfer pattern onto a resist film formed on a transferred substrate.

### Advantageous Effects of Disclosure

According to the present disclosure, it is possible to provide a reflective mask blank, a reflective mask, a method for manufacturing a reflective mask, and a method for manufacturing a semiconductor device, capable of suppressing occurrence of a blister in a reflective mask under an EUV exposure environment in a hydrogen atmosphere.

### BRIEF DESCRIPTION OF DRAWINGS

FIG. 1 is a schematic cross-sectional view illustrating a longitudinal cross-sectional structure of an edge portion of a reflective mask blank according to an embodiment of the present disclosure.

FIG. 2 is a schematic cross-sectional view further illustrating the longitudinal cross-sectional structure of the edge portion of the reflective mask blank according to the embodiment of the present disclosure.

FIG. 3 is a schematic cross-sectional view illustrating the edge portion of the reflective mask blank after edge rinse.

FIG. 4A is a schematic view illustrating a method for manufacturing a reflective mask.

FIG. 4B is a schematic view further illustrating the method for manufacturing a reflective mask.

FIG. 4C is a schematic view further illustrating the method for manufacturing a reflective mask.

FIG. 4D is a schematic view further illustrating the method for manufacturing a reflective mask.

FIG. 4E is a schematic view further illustrating the method for manufacturing a reflective mask.

FIG. 4F is a schematic view further illustrating the method for manufacturing a reflective mask.

FIG. 5 is a diagram illustrating a schematic configuration of an EUV exposure apparatus.

### DESCRIPTION OF EMBODIMENTS

Hereinafter, an embodiment of the present disclosure will be specifically described with reference to the drawings. Note that the following embodiment is a mode for specifically describing the present disclosure and does not limit the present disclosure within the scope thereof.

Here, “on” a substrate or a film includes not only a case of being in contact with a top surface of the substrate or the film but also a case of being not in contact with the top surface of the substrate or the film. That is, “on” a substrate or a film includes a case where a new film is formed above the substrate or the film, a case where another film is interposed between the substrate or the film and an object “on” the substrate or the film, and the like. In addition, “on” does not necessarily mean an upper side in the vertical direction. “On” merely indicates a relative positional relationship among a substrate, a film, and the like.

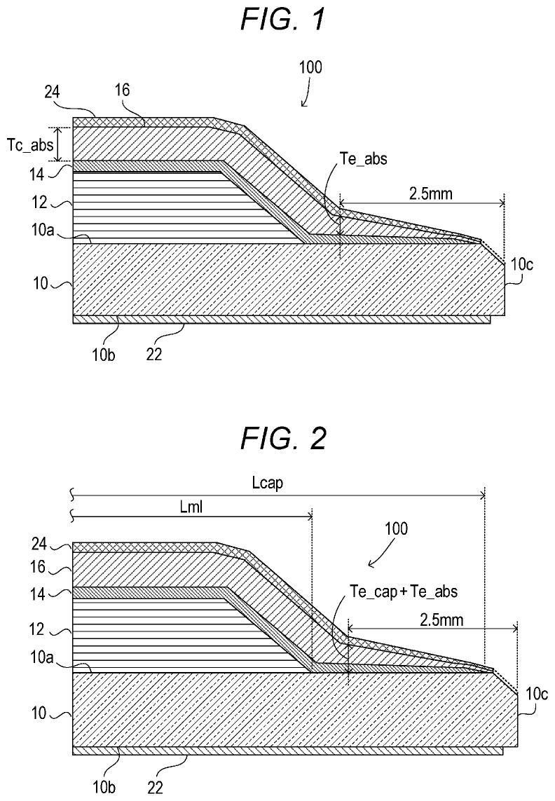

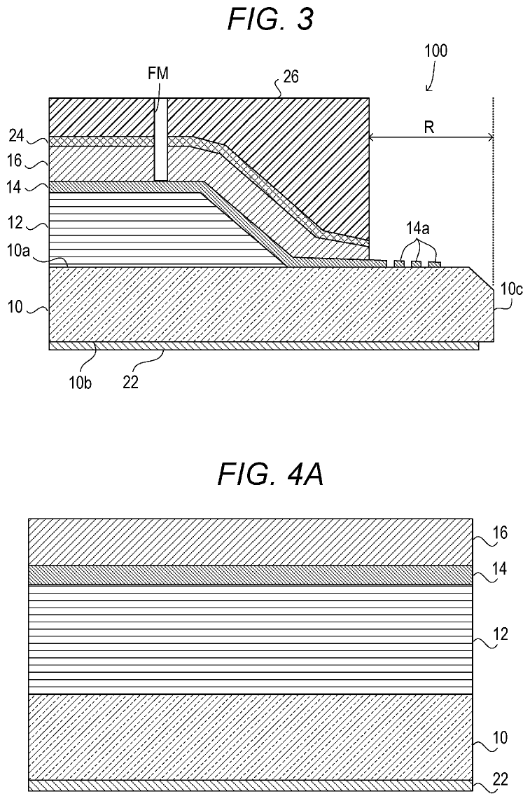

FIGS. 1 and 2 are schematic cross-sectional views illustrating an example of a reflective mask blank 100 of the present embodiment, and are enlarged views of an outer peripheral end portion of a substrate 10. The reflective mask blank 100 illustrated in FIGS. 1 and 2 includes the substrate 10, a multilayer reflective film 12 formed on the substrate 10, a protective film 14 formed on the multilayer reflective film 12, and an absorber film 16 formed on the protective film 14. Note that the absorber film 16 may have a two-layer structure including a buffer layer formed so as to be in contact with the protective film 14 and an absorption layer formed on the buffer layer.

An etching mask film 24 may be formed on the absorber film 16. A conductive back film 22 for electrostatic chuck may be formed on a back surface of the substrate 10 (a main surface 10b on a side opposite to a main surface 10a where the multilayer reflective film 12 is formed).

<Substrate>

As the substrate 10, a substrate having a low thermal expansion coefficient within a range of 0±5 ppb/° C. is preferably used in order to prevent distortion of a transfer pattern due to heat during exposure to EUV light. As a material having a low thermal expansion coefficient within this range, for example, SiO₂—TiO₂-based glass or multicomponent-based glass ceramic can be used.

The main surface 10a of the substrate 10 on a side where a transfer pattern (absorber pattern described later) is formed is preferably processed in order to increase a flatness. By increasing the flatness of the main surface 10a of the substrate 10, position accuracy and transfer accuracy of the pattern can be increased. For example, in a case of EUV exposure, the flatness in a region of 132 mm×132 mm of the main surface 10a of the substrate 10 on the side where the transfer pattern is formed is preferably 0.1 μm or less, more preferably 0.05 μm or less, and particularly preferably 0.03 μm or less. The main surface (back surface) 10b on a side opposite to the side where the transfer pattern is formed is a surface to be fixed to an exposure apparatus by electrostatic chuck, and the flatness in a region of 142 mm×142 mm of the main surface (back surface) 10b is preferably 0.1 μm or less, more preferably 0.05 μm or less, and particularly preferably 0.03 μm or less. Note that here, the flatness is a value indicating warp (deformation amount) of a surface, expressed by total indicated reading (TIR), and an absolute value of a difference in height between the highest position of a substrate surface above a focal plane and the lowest position of the substrate surface below the focal plane, in which the focal plane is a plane defined by a minimum square method using the substrate surface as a reference.

In a case of EUV exposure, the main surface 10a of the substrate 10 on the side where the transfer pattern is formed preferably has a surface roughness of 0.1 nm or less in terms of root mean square roughness (Rq). Note that the surface roughness can be measured with an atomic force microscope.

The substrate 10 preferably has a high rigidity in order to prevent deformation of a film (such as the multilayer reflective film 12) formed on the substrate 10 due to a film stress. In particular, the substrate 10 preferably has a high Young's modulus of 65 GPa or more.

<Multilayer Reflective Film>

The multilayer reflective film 12 has a structure in which a plurality of layers mainly containing elements having different refractive indices is periodically layered. Generally, the multilayer reflective film 12 is formed of a multilayer film in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods. In order to form the multilayer reflective film 12, the high refractive index layer and the low refractive index layer may be layered in this order from the substrate 10 side for a plurality of periods. In this case, one (high refractive index layer/low refractive index layer) stack is one period.

Note that an uppermost layer of the multilayer reflective film 12, that is, a surface layer of the multilayer reflective film 12 on a side opposite to the substrate 10 is preferably the high refractive index layer. When the high refractive index layer and the low refractive index layer are built up in this order from the substrate 10 side, the uppermost layer is the low refractive index layer. However, when the low refractive index layer forms a surface of the multilayer reflective film 12, the reflectance of the surface of the multilayer reflective film 12 is reduced due to easy oxidation of the low refractive index layer. Therefore, the high refractive index layer is preferably formed on the low refractive index layer. Meanwhile, when the low refractive index layer and the high refractive index layer are built up in this order from the substrate 10 side, the uppermost layer is the high refractive index layer. In this case, the high refractive index layer as the uppermost layer is a surface of the multilayer reflective film 12.

The high refractive index layer included in the multilayer reflective film 12 is a layer made of a material containing Si. The high refractive index layer may contain a simple substance of Si or a Si compound. The Si compound may contain Si and at least one element selected from the group consisting of B, C, N, O, and H. By using the layer containing Si as the high refractive index layer, a multilayer reflective film having an excellent reflectance of EUV light can be obtained.

The low refractive index layer included in the multilayer reflective film 12 is a layer made of a material containing a transition metal. The transition metal contained in the low refractive index layer is preferably at least one transition metal selected from the group consisting of Mo, Ru, Rh, and Pt. The low refractive index layer is more preferably a layer made of a material containing Mo.

For example, as the multilayer reflective film 12 for EUV light having a wavelength of 13 to 14 nm, a Mo/Si multilayer film in which a Mo film and a Si film are alternately layered for about 40 to 60 periods can be preferably used.

The reflectance of such a multilayer reflective film 12 alone is, for example, 65% or more. An upper limit of the reflectance of the multilayer reflective film 12 is, for example, 73%. Note that the thicknesses and period of layers included in the multilayer reflective film 12 can be selected so as to satisfy Bragg's law.

The multilayer reflective film 12 can be formed by a known method. The multilayer reflective film 12 can be formed by, for example, an ion beam sputtering method.

For example, when the multilayer reflective film 12 is a Mo/Si multilayer film, a Mo film having a thickness of about 3 nm is formed on the substrate 10 by an ion beam sputtering method using a Mo target. Next, a Si film having a thickness of about 4 nm is formed using a Si target. By repeating such an operation, the multilayer reflective film 12 in which Mo/Si films are layered for 40 to 60 periods can be formed. At this time, a surface layer of the multilayer reflective film 12 on a side opposite to the substrate 10 is a layer containing Si (Si film). The Mo/Si film in one period has a thickness of 7 nm.

<Protective Film>

The reflective mask blank 100 of the present embodiment includes the protective film 14 formed on the multilayer reflective film 12. The protective film 14 has a function of protecting the multilayer reflective film 12 from dry etching and cleaning in a reflective mask 110 manufacturing process described later. The protective film 14 also has a function of protecting the multilayer reflective film 12 when a black defect in a transfer pattern is corrected using an electron beam (EB). By forming the protective film 14 on the multilayer reflective film 12, damage to a surface of the multilayer reflective film 12 can be suppressed when the reflective mask 110 is manufactured. As a result, a reflectance characteristic of the multilayer reflective film 12 with respect to EUV light is improved.

The protective film 14 can be formed by a known method. Examples of a method for forming the protective film 14 include an ion beam sputtering method, a magnetron sputtering method, a reactive sputtering method, a vapor phase growth method (CVD), and a vacuum vapor deposition method. The protective film 14 may be continuously formed by an ion beam sputtering method after the multilayer reflective film 12 is formed.

The protective film 14 can be made of a material having different etching selectivity from the absorber film 16. Examples of the material of the protective film 14 include Ru, Ru—(Nb, Rh, Zr, Y, B, Ti, La, Mo), Si—(Ru, Rh, Cr, B), Si, Zr, Nb, La, and B. Among these materials, when a material containing ruthenium (Ru) is applied, a reflectance characteristic of the multilayer reflective film 12 is further improved. Specifically, the material of the protective film 14 is preferably Ru or Ru—(Nb, Rh, Zr, Y, B, Ti, La, Mo). Such a protective film 14 is particularly effective in a case where the absorber film 16 is made of a Ta-based material and patterned by dry etching with a Cl-based gas.

<Absorber Film>

The absorber film 16 on which a transfer pattern is formed may be a layer for the purpose of absorbing EUV light, or may be a layer having a phase shift function in consideration of a phase difference of EUV light. The absorber film 16 having a phase shift function absorbs EUV light and reflects a part of the EUV light to shift a phase. That is, in the reflective mask in which the absorber film 16 having a phase shift function is patterned, in a portion where the absorber film 16 is formed, a part of light is reflected at a level that does not adversely affect pattern transfer while EUV light is absorbed and attenuated. In addition, in a region (field portion) where the absorber film 16 is not formed, EUV light is reflected by the multilayer reflective film 12 via the protective film 14. Therefore, a desired phase difference is generated between reflected light from the absorber film 16 having a phase shift function and reflected light from the field portion. The absorber film 16 having a phase shift function is preferably formed such that a phase difference between reflected light from the absorber film 16 and reflected light from the multilayer reflective film 12 is 170 to 190 degrees. Beams of light having a reversed phase difference around 180 degrees interfere with each other at a pattern edge portion to improve an image contrast of a projected optical image. As the image contrast is improved, resolution is increased, and various exposure-related margins such as an exposure margin and a focus margin can be increased.

The absorber film 16 may be a single layer film or a multilayer film formed of a plurality of films. In a case of a single layer film, the number of steps at the time of manufacturing the mask blank can be reduced, and manufacturing efficiency is increased. In a case of the multilayer film, an optical constant of an upper absorption layer and the film thickness thereof can be appropriately set such that the upper absorption layer serves as an antireflection film at the time of mask pattern defect inspection using light. This improves inspection sensitivity at the time of mask pattern defect inspection using light. In addition, when a film containing oxygen (O), nitrogen (N), and the like that improve oxidation resistance is used as the upper absorption layer, temporal stability is improved. As described above, by forming the absorber film 16 into a multilayer film, various functions can be added to the absorber film 16. When the absorber film 16 has a phase shift function, by forming the absorber film 16 into a multilayer film, a range of adjustment on an optical surface can be increased, and therefore a desired reflectance can be easily obtained.

A material of the absorber film 16 is not particularly limited as long as the material has a function of absorbing EUV light, can be processed by etching or the like (preferably, can be etched by dry etching with a chlorine (Cl)-based gas and/or a fluorine (F)-based gas), and has a high etching selective ratio to the protective film 14. As a material having such a function, at least one metal selected from tantalum (Ta), palladium (Pd), zirconium (Zr), hafnium (Hf), yttrium (Y), niobium (Nb), vanadium (V), titanium (Ti), lanthanum (La), scandium (Sc), palladium (Pd), silver (Ag), platinum (Pt), gold (Au), iridium (Ir), tungsten (W), chromium (Cr), cobalt (Co), manganese (Mn), tin (Sn), nickel (Ni), iron (Fe), copper (Cu), tellurium (Te), zinc (Zn), magnesium (Mg), germanium (Ge), aluminum (Al), rhodium (Rh), ruthenium (Ru), molybdenum (Mo), and silicon (Si), or a compound thereof can be preferably used. In particular, even when the absorber film 16 contains at least one selected from tantalum (Ta), palladium (Pd), zirconium (Zr), hafnium (Hf), yttrium (Y), niobium (Nb), vanadium (V), titanium (Ti), lanthanum (La), and scandium (Sc) having relatively high hydrogen storage characteristics, occurrence of a blister at a substrate edge portion can be suppressed.

As illustrated in FIG. 1, the film thickness of the absorber film 16 at a center of the substrate 10 (referred to as “center portion film thickness Tc_abs”) is preferably 30 nm or more, and more preferably 40 nm or more. An average film thickness over the entire surface of the absorber film 16 is preferably 80 nm or less, and more preferably 70 nm or less. In addition, there is preferably at least one location where a maximum film thickness of the absorber film 16 measured in a range of 2.5 mm or less from a side surface 10c of the substrate 10 toward the center thereof (referred to as “edge portion film thickness Te_abs”) is 35 nm or less. In addition, even in a case where the center portion film thickness Tc_abs is smaller than 40 nm, when the film thickness Tc_abs is T nm, there is preferably at least one location where the edge portion film thickness Te_abs measured in a range of 2.5 mm or less from the side surface 10c of the substrate 10 toward the center thereof is (T−5) nm or less. In addition, there is preferably at least one location where the edge portion film thickness Te_abs is 35 nm or less and (T−5) nm or less. Furthermore, there is preferably at least one location where the edge portion film thickness Te_abs is 35 nm or less and (T−5) nm or less on all of the four side surfaces 10c of the substrate 10.

Note that here, the “center of the substrate” means a position on the main surface 10a (or 10b) where the center of gravity of the substrate 10 is located. For example, when the substrate 10 is a quadrangle, the position of a point at which two diagonal lines intersect with each other on the main surface 10a (or 10b) corresponds to the “center of the substrate”. The “side surface of the substrate” means the surface 10c substantially perpendicular to the two main surfaces 10a and 10b in an outer peripheral end portion of the substrate 10, and may be referred to as a “T surface”. In addition, the “outer peripheral end” of a film or a layer means an end of the film or the layer at a position farthest from the center of the substrate 10.

The absorber film 16 can be formed by a magnetron sputtering method such as a DC sputtering method or an RF sputtering method. For example, the absorber film 16 such as a tantalum compound can be formed by a reactive sputtering method using a target containing tantalum and boron and using an argon gas containing oxygen or nitrogen. A film forming region (a distance from the center of the substrate to the outer peripheral end), an inclined cross-sectional shape (gradient profile), and the like of the absorber film 16 in the edge portion of the substrate 10 can be appropriately adjusted by an opening dimension of a PVD shield, a tapered shape of an opening, an interval between the shield and the substrate, and the like. In addition, the film thickness of the absorber film 16 can be adjusted by film forming time by a magnetron sputtering method.

Note that the film thickness of the absorber film 16 formed near the edge portion by sputtering via the PVD shield having an opening at a center monotonically increases from the side surface 10c of the substrate 10 toward the center thereof. Assuming such a slope of the film thickness, for example, when the film thickness is measured at a position of 2.5 mm from the side surface 10c of the substrate 10 toward the center thereof, and a film thickness of 35 nm or less is measured at least at one location among the positions, it can be said that “There is at least one location having a film thickness of 35 nm or less in a range of 2.5 mm or less from the side surface 10c of the substrate 10 toward the center thereof”.

The tantalum compound for forming the absorber film 16 includes an alloy made of Ta and the above-described metal. When the absorber film 16 is an alloy of Ta, a crystalline state of the absorber film 16 is preferably an amorphous or microcrystalline structure from a viewpoint of smoothness and flatness. When a surface of the absorber film 16 is not smooth or not flat, an absorber pattern described later may have a large edge roughness and a poor pattern dimensional accuracy. The absorber film 16 has a surface roughness of preferably 0.5 nm or less, more preferably 0.4 nm or less, still more preferably 0.3 nm or less in terms of root mean square roughness (Rms).

Examples of the tantalum compound for forming the absorber film 16 include a compound containing Ta and B, a compound containing Ta and N, a compound containing Ta, O, and N, a compound containing Ta and B and further containing at least either O or N, a compound containing Ta and Si, a compound containing Ta, Si, and N, a compound containing Ta and Ge, a compound containing Ta, Ge, and N, and the like.

Ta is a material that has a large absorption coefficient of EUV light and can be easily dry-etched with a chlorine-based gas or a fluorine-based gas. Therefore, Ta can be said to be a material having excellent processability for the absorber film 16. By further adding B, Si, and/or Ge, or the like to Ta, an amorphous material can be easily obtained. As a result, the smoothness of the absorber film 16 can be improved. In addition, when N and/or O is added to Ta, resistance of the absorber film 16 to oxidation is improved, and therefore stability of the absorber film 16 over time can be improved.

<Etching Mask Film>

The etching mask film 24 may be formed on the absorber film 16. As a material of the etching mask film 24, a material having a high etching selective ratio of the absorber film 16 to the etching mask film 24 is preferably used. The etching selective ratio of the absorber film 16 to the etching mask film 24 is preferably 1.5 or more, and more preferably 3 or more.

The reflective mask blank 100 of the present embodiment preferably includes the etching mask film 24 containing chromium (Cr) on the absorber film 16. When the absorber film 16 is etched with a fluorine-based gas, as a material of the etching mask film 24, chromium or a chromium compound is preferably used. Examples of the chromium compound include a material containing Cr and at least one element selected from N, O, C, and H. The etching mask film 24 more preferably contains CrN, CrO, CrC, CrON, CrOC, CrCN, or CrOCN, and is still more preferably a CrO-based film containing chromium and oxygen (CrO film, CrON film, CrOC film, or CrOCN film).

When the absorber film 16 is etched with a chlorine-based gas substantially containing no oxygen, silicon material or a silicon compound is preferably used as a material of the etching mask film 24. Examples of the silicon compound include a material containing Si and at least one element selected from N, O, C, and H, a metal silicon (metal silicide) containing silicon and a metal, a metal silicon compound (metal silicide compound) containing a silicon compound and a metal, and the like. Examples of the metal silicon compound include a material containing a metal, Si, and at least one element selected from N, O, C, and H.

The film thickness of the etching mask film 24 is preferably 3 nm or more in order to accurately form a pattern on the absorber film 16. In addition, the film thickness of the etching mask film 24 is desirably 15 nm or less in order to reduce the film thickness of a resist film 26.

<Conductive Back Film>

A conductive back film 22 for electrostatic chuck may be formed on a back surface of the substrate 10 (main surface 10b opposite to a side where the multilayer reflective film 12 is formed). Sheet resistance required for the conductive back film 22 for electrostatic chuck is usually 100 Ω/square or less. The conductive back film 22 can be formed, for example, by a magnetron sputtering method or an ion beam sputtering method using a target of a metal such as chromium or tantalum or an alloy thereof. A material of the conductive back film 22 is preferably a material containing chromium (Cr) or tantalum (Ta). For example, the material of the conductive back film 22 is preferably a Cr compound containing Cr and at least one selected from boron, nitrogen, oxygen, and carbon. Examples of the Cr compound include CrN, CrON, CrCN, CrCON, CrBN, CrBON, CrBCN, CrBOCN, and the like. In addition, the material of the conductive back film 22 is preferably Ta (tantalum), an alloy containing Ta, or a Ta compound containing either Ta or an alloy containing Ta and at least one of boron, nitrogen, oxygen, and carbon. Examples of the Ta compound include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, TaSiCON, and the like.

The film thickness of the conductive back film 22 is not particularly limited as long as the conductive back film 22 functions as a film for electrostatic chuck, but is preferably, for example, 10 nm to 200 nm.

In EUV lithography performed in a hydrogen atmosphere, there is a problem that a blister occurs in the stack of the reflective mask. In particular, when such a blister occurs at an edge portion of the substrate, film peeling that has occurred from the blister as a starting point scatters on the multilayer reflective film, the absorber film, or the like, and use as a reflective mask is impossible. Therefore, in the reflective mask blank 100 of the present embodiment, in order to suppress occurrence of a blister, for example, as illustrated in FIG. 1, there is at least one location where the edge portion film thickness Te_abs of the absorber film 16 in a range of 2.5 mm or less from the side surface 10c of the substrate 10 toward the center thereof is the smaller of 35 nm or less or (T−5) nm or less when the center portion film thickness Tc_abs of the absorber film 16 at the center of the substrate 10 is T nm. In addition, there is preferably at least one location where the edge portion film thickness Te_abs is 35 nm or less and (T−5) nm or less. Furthermore, there is preferably at least one location where the edge portion film thickness Te_abs is 35 nm or less and (T−5) nm or less on all of the four side surfaces 10c of the substrate 10.

As described above, hydrogen decomposed by EUV light is taken into layers of the layered film, a hydrogen internal pressure increases at a specific film interface, and a stress of the absorber film 16 applies a load to the interface having a high hydrogen internal pressure on a lower layer side, which are factors of occurrence of a blister. In addition, in a film having a thickness of several nm to several 100 nm, the stress of the film is proportional to the thickness of the film. Therefore, in the reflective mask blank 100 of the present embodiment, the edge portion film thickness Te_abs of the absorber film 16 is the smaller of 35 nm or (T−5) nm or less when the center portion film thickness Tc_abs is T nm, and a load of a stress applied by the absorber film 16 to the multilayer reflective film 12 and the like on a lower layer side is thereby reduced. As a result, the load applied to an interface of the multilayer reflective film 12 and the like is suppressed, and as a result, occurrence of a blister due to the load applied to the interface of these films can be suppressed. Note that the edge portion film thickness Te_abs of the absorber film 16 can be 0 nm from a viewpoint of suppressing occurrence of a blister.

In addition, in the reflective mask blank 100 of the present embodiment, the absorber film 16 contains at least one selected from tantalum (Ta), palladium (Pd), zirconium (Zr), hafnium (Hf), yttrium (Y), niobium (Nb), vanadium (V), titanium (Ti), lanthanum (La), and scandium (Sc). Since these elements have relatively high hydrogen storage characteristics, the material of the absorber film 16 contains these elements, and hydrogen is thereby easily taken into the absorber film 16 under EUV exposure. Therefore, by setting the edge portion film thickness Te_abs of the absorber film 16 as described above, occurrence of a blister can be suppressed even when the material of the absorber film 16 contains these elements.

Although details will be described later, in a case of manufacturing the reflective mask 110 using the reflective mask blank 100, first, the resist film 26 for electron beam drawing is formed on a surface of the reflective mask blank 100. Next, a desired pattern is drawn on the resist film 26 with an electron beam, and the pattern is developed to form a resist pattern. Next, using the resist pattern as a mask, the absorber film is dry-etched to form an absorber pattern (transfer pattern). As a result, it is possible to manufacture a reflective mask in which the absorber pattern is formed on the multilayer reflective film.

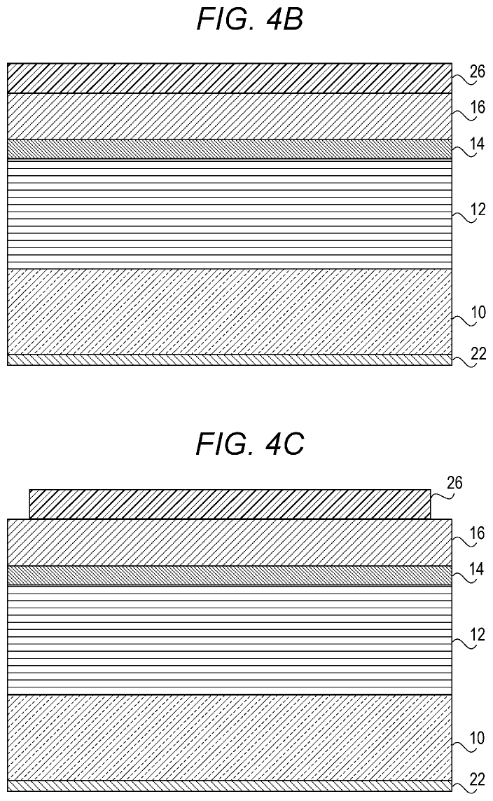

In a reflective mask 110 manufacturing process, the resist film 26 is formed on the entire surface of the reflective mask blank 100, but in order to prevent the resist film 26 from being peeled off and generating dust at an edge of the substrate 10, edge rinse for removing the resist film 26 at the edge portion where the mask pattern is not formed is usually performed (see, for example, FIG. 3). In addition, a reference mark FM (Fiducial Mark) for managing a position of a defect on the multilayer reflective film 12 may be formed. In order to protect the multilayer reflective film 12 at the edge portion from dry etching, cleaning, or the like in preprocessing of such a mask manufacturing process, with respect to a distance Lml from the center of the substrate 10 to an outer peripheral end of the multilayer reflective film 12, a distance Lcap from the center of the substrate 10 to an outer peripheral end of the protective film 14 preferably satisfies Lml<Lcap. In addition, Lcap<Labs is preferably satisfied with respect to a distance Labs from the center of the substrate 10 to an outer peripheral end of the absorber film 16.

As illustrated in FIG. 3, in a region R from which the resist film 26 has been removed by edge rinse, an isolated island-shaped protective film 14a may be formed by dry etching at the time of forming the reference mark FM or forming a transfer pattern. The isolated island-shaped protective film 14a is a portion separated from a periphery thereof, and is not connected to the protective film 14 on the center side of the substrate 10. When such an isolated island-shaped protective film 14a is present, electricity charged in the isolated island-shaped protective film 14a is discharged at once at the time of electron beam drawing for pattern formation, and electrostatic breakdown (ESD) may occur. In order to prevent formation of the isolated island-shaped protective film 14a that can also be a factor of electrostatic breakdown, for example, as illustrated in FIG. 2, there is preferably at least one location where the total film thickness (Te_cap+Te_abs) of the protective film 14 and the absorber film 16 in a range of 2.5 mm or less from the side surface 10c of the substrate 10 toward the center thereof is 4.5 nm or more. A case where Lcap<Labs is satisfied also includes a case where Te_cap in a range of 2.5 mm or less from the side surface 10c of the substrate 10 toward the center thereof is zero. In this case, there is preferably at least one location where the film thickness Te_abs of the absorber film 16 in a range of 2.5 mm or less from the side surface 10c of the substrate 10 toward the center thereof is 4.5 nm or more.

<Method for Manufacturing Reflective Mask>

Using the reflective mask blank 100 of the present embodiment, the reflective mask 110 of the present embodiment can be manufactured. Hereinafter, an example of a method for manufacturing the reflective mask 110 will be described.

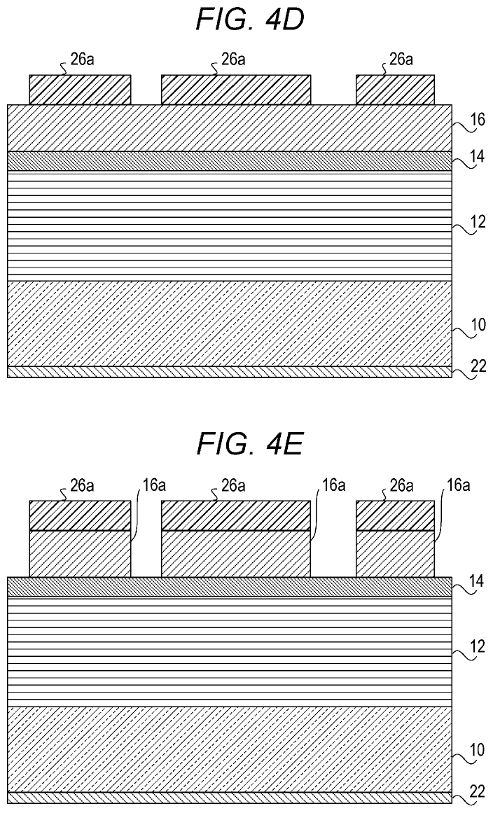

FIG. 4 is a schematic view illustrating an example of a method for manufacturing the reflective mask 110. As illustrated in FIG. 4, first, the reflective mask blank 100 including the substrate 10, the multilayer reflective film 12 formed on the main surface 10a of the substrate 10, the protective film 14 formed on the multilayer reflective film 12, the absorber film 16 formed on the protective film 14, and the conductive back film 22 formed on the main surface 10b that is a back surface of the substrate 10 is prepared (FIG. 4A). Next, the resist film 26 is formed on the absorber film 16 (FIG. 4B). In order to suppress generation of dust due to peeling of the resist film 26, the resist film 26 at an edge portion is removed with a solvent in which the resist film 26 is dissolved (edge rinse) (FIG. 4C). The edge rinse is performed along a peripheral edge portion of the substrate 10 with a width of about 1 to 1.5 mm. A pattern is drawn on the resist film 26 with an electron beam drawing device, and then the resulting product is subjected to a development and rinse step to form a resist pattern 26a (FIG. 4D).

The absorber film 16 is dry-etched using the resist pattern 26a as a mask. As a result, a portion not covered with the resist pattern 26a in the absorber film 16 is etched to form an absorber pattern 16a (FIG. 4E).

As an etching gas for the absorber film 16, for example, a fluorine-based gas and/or a chlorine-based gas can be used. As the fluorine-based gas, CF₄, CHF₃, C₂F₆, C₃F₆, C₄F₆, C₄F₈, CH₂F₂, CH₃F, C₃F₈, SF₆, F₂, and the like can be used. As a chlorine-based gas, Cl₂, SiCl₄, CHCl₃, CCl₄, BCl₃, and the like can be used. In addition, a mixed gas containing a fluorine-based gas and/or a chlorine-based gas and O₂ at a predetermined ratio can be used. These etching gases can each further contain an inert gas such as He and/or Ar, if necessary.

After the absorber pattern 16a is formed, the resist pattern 26a is removed with a resist peeling liquid. After the resist pattern 26a is removed, the resulting product is subjected to a wet cleaning step using an acidic or alkaline aqueous solution to obtain the reflective mask 110 of the present embodiment (FIG. 4F).

Note that, when the reflective mask blank 100 including the etching mask film 24 on the absorber film 16 is used, a step of forming a pattern (etching mask pattern) on the etching mask film 24 using the resist pattern 26a as a mask and then forming a pattern on the absorber film 16 using the etching mask pattern as a mask is added.

The reflective mask 110 thus obtained has a structure in which the multilayer reflective film 12, the protective film 14, and the absorber pattern 16a are layered on the substrate 10.

<Method for Manufacturing Semiconductor Device>

A transfer pattern can be formed on a semiconductor substrate (transferred substrate) 60 by lithography using the reflective mask 110 of the present embodiment. This transfer pattern has a shape in which a pattern of the reflective mask 110 is reduced. By forming a transfer pattern on the semiconductor substrate 60 with the reflective mask 110, a semiconductor device can be manufactured.

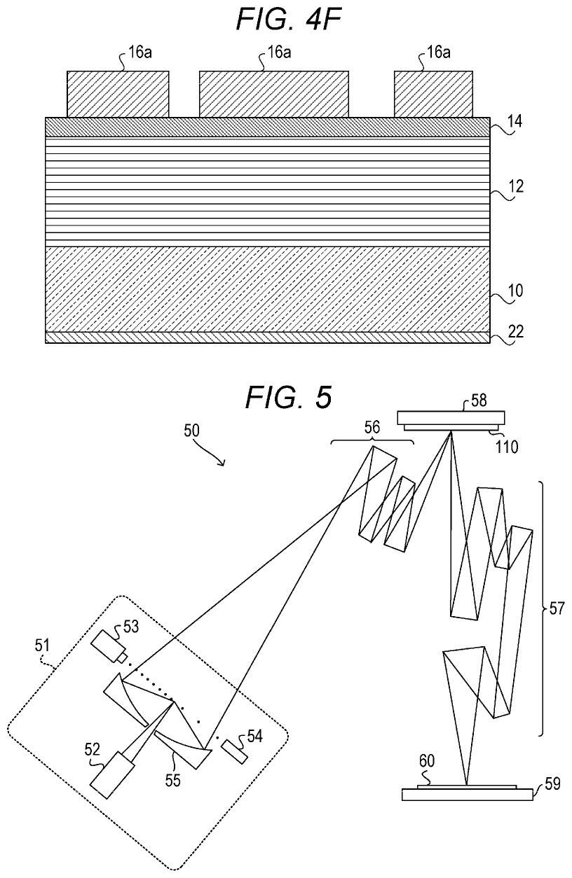

FIG. 5 illustrates a schematic configuration of an EUV exposure apparatus 50 that is an apparatus for transferring a transfer pattern onto a resist film formed on the semiconductor substrate 60. In the EUV exposure apparatus 50, an EUV light generation unit 51, an irradiation optical system 56, a reticle stage 58, a projection optical system 57, and a wafer stage 59 are precisely arranged along an optical path axis of EUV light. A container of the EUV exposure apparatus 50 is filled with a hydrogen gas.

The EUV light generation unit 51 includes a laser light source 52, a tin droplet generation unit 53, a catching unit 54, and a collector 55. When a tin droplet emitted from the tin droplet generation unit 53 is irradiated with a high-power carbon dioxide laser from the laser light source 52, tin in a droplet state is turned into plasma to generate EUV light. The generated EUV light is collected by the collector 55, passes through the irradiation optical system 56, and enters the reflective mask 110 set on the reticle stage 58. The EUV light generation unit 51 generates, for example, EUV light having a wavelength of 13.53 nm.

EUV light reflected by the reflective mask 110 is usually reduced to about ¼ of pattern image light by the projection optical system 57 and projected on the semiconductor substrate 60 (transferred substrate). As a result, a given circuit pattern is transferred onto the resist film on the semiconductor substrate 60.

The resist film that has been subjected to exposure is developed, whereby a resist pattern can be formed on the semiconductor substrate 60. By etching the semiconductor substrate 60 using the resist pattern as a mask, an integrated circuit pattern can be formed on the semiconductor substrate 60. A semiconductor device can be manufactured through such a step and other necessary steps.

### EXAMPLES

Hereinafter, Examples (Sample Nos. 1 to 10) and Comparative Examples (Sample Nos. 11 to 13) of the reflective mask blank according to the present disclosure will be described with reference to Table 1.

TABLE 1

| | | Absorber film | | | Protective film | | | |
|---|---|---|---|---|---|---|---|---|
| | | | Center | Edge | Edge | | | |
| | | | portion film | portion film | portion film | Film | Evaluation | |
| | Sample | | thickness | thickness | thickness | forming | Occurrence | Occurrence |
| | No. | Material | Tc_abs (nm) | Te_abs (nm) | Te_cap (nm) | region | of blister | of ESD |
| Example | 1 | TaBN | 70 | 35 | 3.5 | Lml < Lcap | — | — |
| | 2 | | 70 | 15 | 3.5 | | — | — |
| | 3 | | 70 | 1.4 | 3.5 | | — | — |
| | 4 | | 70 | 0.7 | 3.5 | | — | Occurred |
| | 5 | | 50 | 1.2 | 3.5 | | — | — |
| | 6 | | 40 | 1.1 | 3.5 | | — | — |
| | 7 | | 30 | 20 | 3.5 | | — | — |
| | 8 | PdN | 50 | 35 | 3.5 | | — | — |
| | 9 | | 35 | 20 | 3.5 | | — | — |
| | 10 | | 50 | 1.4 | 3.5 | | — | — |
| Comparative | 11 | TaBN | 70 | 48 | 3.5 | Lml < Lcap | Occurred | — |
| Example | 12 | | 35 | 33 | 3.5 | | Occurred | — |
| | 13 | | 70 | 68 | 0 | Lml ≥ Lcap | Occurred | — |

Here, in Table 1,
Tc_abs means a center portion film thickness of an absorber film,
Te_abs means a maximum film thickness of an absorber film in a range of 2.5 mm or less from a side surface of a substrate toward a center thereof,
Te_cap means a maximum film thickness of a protective film in a range of 2.5 mm or less from the side surface of the substrate toward the center thereof,
Lml means a distance from the center of the substrate to an outer peripheral end of a multilayer reflective film,
Lcap means a distance from the center of the substrate to an outer peripheral end of the protective film, and
ESD means electrostatic breakdown.

<Substrate>

For each of the reflective mask blanks of Sample Nos. 1 to 13, a substrate having a size of 6025 (about 152 mm×152 mm×6.35 mm) was prepared. The substrate is made of low thermal expansion glass (SiO₂—TiO₂-based glass). A main surface of the substrate was polished by rough polishing, precision polishing, local processing, and touch polishing so as to have a root mean square roughness (Rq) of 0.1 nm or less.

<Multilayer Reflective Film>

A multilayer reflective film was formed on a main surface of the prepared substrate. The multilayer reflective film was a periodic multilayer reflective film containing Mo and Si in order to make the multilayer reflective film suitable for EUV light having a wavelength of 13.5 nm. The Mo/Si multilayer reflective film was formed by alternately building up a Mo film and a Si film on the substrate 10 using a Mo target and a Si target by an ion beam sputtering method using krypton (Kr) as a process gas. First, a Si film was formed with a thickness of 4.2 nm, and then a Mo film was formed with a thickness of 2.8 nm. This stack was counted as one period, and the Si film and the Mo film were built up for 40 periods in a similar manner. Then, finally, the Si film was formed with a thickness of 4.0 nm. A mask shield used for sputtering of the multilayer reflective film had an opening dimension of 147×147 mm.

<Protective Film>

A RuNb protective film was formed on the multilayer reflective film using a RuNb target in an Ar gas atmosphere by a magnetron sputtering method. The protective film of each of the samples had a film thickness of 3.5 nm.

Sample Nos. 1 to 12 are Examples and Comparative Examples in which the samples were formed such that Lml<Lcap was satisfied when a distance from a center of the substrate to an outer peripheral end of the multilayer reflective film was denoted by Lml, and a distance from the center of the substrate to an outer peripheral end of the protective film was denoted by Lcap. A mask shield used for sputtering of the protective films of Sample Nos. 1 to 12 had an opening dimension of 150×150 mm. In Sample No. 13, a protective film was formed such that Lml>Lcap was satisfied.

<Absorber Film>

Next, an absorber film was formed on the protective film by a magnetron sputtering method. In Sample Nos. 1 to 7 and 11 to 13, TaBN was used as a material of the absorber film. The TaBN film was formed by a reactive sputtering method using a TaB target in a mixed gas atmosphere of an Ar gas and a N₂ gas. In Sample Nos. 8 to 10, PdN was used as a material of the absorber film. The PdN film was formed by a reactive sputtering method using a Pd target in a mixed gas atmosphere of an Ar gas and a N₂ gas.

For formation of the absorber films of Sample Nos. 1, 2, and 7 to 9, a mask shield having an opening dimension of 147×147 mm was used such that the film thickness Te_abs of the edge portion was a numerical value illustrated in Table 1.

For formation of the absorber films of Sample Nos. 3 to 6 and 10, a mask shield having an opening dimension of 148.5×148.5 mm was used such that the film thickness Te_abs of the edge portion was a numerical value illustrated in Table 1.

In addition, in Sample Nos. 11 to 13 according to Comparative Examples, a mask shield having an opening dimension of 150×150 mm was used such that the film thickness Te_abs of the edge portion of the absorber film was a numerical value illustrated in Table 1.

Sample Nos. 1 to 6, 8, and 10 are Examples in which the film thickness Tc_abs of the absorber film at the center of the substrate is 40 nm or more, and there is at least one location where the film thickness Te_abs of the absorber film in a range of 2.5 mm or less from a side surface of the substrate toward a center thereof is 35 nm or less.

Sample Nos. 7 and 9 are Examples in which the film thickness Tc_abs of the absorber film at the center of the substrate is less than 40 nm, but there is at least one location where the edge portion film thickness Te_abs is (T−5) nm or less when the center portion film thickness Tc_abs is T nm.

<Evaluation>

Using the reflective mask blanks of Sample Nos. 1 to 10 according to Examples and Sample Nos. 11 to 13 according to Comparative Examples, reflective masks were manufactured by the above-described manufacturing method. Note that when the absorber film was a TaBN film, an absorber pattern was formed by dry etching using a Cl₂ gas. When the absorber film was a PdN film, an absorber pattern was formed by dry etching using a Cl₂ gas. When EUV exposure was performed using the reflective masks manufactured from the reflective mask blanks of Sample Nos. 1 to 10 according to Examples, an upper surface of an outermost peripheral portion was observed with an optical microscope, and no blister occurred in any of the samples. Meanwhile, when the reflective masks manufactured from the reflective mask blanks of Sample Nos. 11 to 13 according to Comparative Examples were used, a blister was observed between the edge portion of the surface if the substrate and the protective film.

The reflective mask blanks of Sample Nos. 1 to 3 and 5 to 12 are examples in which the total film thickness of the edge portion film thickness Te_cap of the protective film and the edge portion film thickness Te_abs of the absorber film in a range of 2.5 mm or less from a side surface of the substrate toward a center thereof is 4.5 nm or more. In the reflective masks manufactured from the reflective mask blanks of Sample Nos. 1 to 3 and 5 to 12, an upper surface of an outermost peripheral portion was observed with TEM, and no trace of electrostatic breakdown was confirmed at the edge portion of the substrate. Meanwhile, in the reflective mask manufactured from the reflective mask blank of Sample No. 4 in which the total film thickness of the edge portion film thickness Te_cap of the protective film and the edge portion film thickness Te_abs of the absorber film was thinner than 4.5 nm, a trace of electrostatic breakdown considered to have occurred in the electron beam drawing process was observed at the edge portion of the substrate.

### REFERENCE SIGNS LIST

10 Substrate
12 Multilayer reflective film
14 Protective film
16 Absorber film (16a: absorber pattern)
22 Conductive back film
24 Etching mask film
26 Resist film
50 EUV exposure apparatus
51 EUV light generation unit (exposure generation unit)
56 Irradiation optical system
57 Projection optical system
58 Reticle stage
59 Wafer stage
60 Semiconductor substrate (transferred substrate)
100 Reflective mask blank
110 Reflective mask
Lcap Distance from center of substrate to outer peripheral end of protective film
Lml Distance from center of substrate to outer peripheral end of multilayer reflective film
Tc_abs Film thickness at center portion of absorber film
Te_abs Film thickness at edge portion of absorber film
Te_cap Film thickness at edge portion of protective film

1. A reflective mask blank comprising: a substrate; a multilayer reflective film above the substrate; a protective film above the multilayer reflective film; and an absorber film above the protective film, wherein
film thickness of the absorber film at a center of the substrate is T nm, and a film thickness of a portion of the absorber film in an area that is less than 2.5 nm from at least one edge of the substrate a less than or equal to a smaller of 35 nm or (T−5) nm.

2. The reflective mask blank according to claim 1, wherein
a distance from the center of the substrate to an outer peripheral end of the multilayer reflective film is denoted by Lml, and a distance from the center of the substrate to an outer peripheral end of the protective film is denoted by Lcap, and wherein Lml<Lcap, and
wherein combined film thickness of the protective film and the absorber film is 4.5 nm or more in the area that is less than 2.5 nm near the at least one edge of the substrate.

3. The reflective mask blank according to claim 1, wherein the absorber film comprises at least one of tantalum (Ta), palladium (Pd), zirconium (Zr), hafnium (Hf), yttrium (Y), niobium (Nb), vanadium (V), titanium (Ti), lanthanum (La), and scandium (Sc).

4. The reflective mask blank according to claim 1, wherein the film thickness T nm of the absorber film at the center of the substrate is at least 30 nm.

5. The reflective mask blank according to claim 1, wherein the protective film comprises ruthenium (Ru).

6. A reflective mask comprising: a substrate; a multilayer reflective film above the substrate; a protective film above the multilayer reflective film; and an absorber film with an absorber pattern above the protective film, wherein
a film thickness of the absorber film at a center of the substrate is T nm, and a film thickness of a portion of the absorber film in an area that is less than 2.5 nm from at least one edge of the substrate is a less than or equal to a smaller of 35 nm or (T−5) nm.

7. (canceled)

8. (canceled)

9. The reflective mask blank according to claim 1, wherein the absorber film comprises at least one of silver (Ag), platinum (Pt), gold (Au), iridium (Ir), tungsten (W), chromium (Cr), cobalt (Co), manganese (Mn), tin (Sn), nickel (Ni), iron (Fe), copper (Cu), tellurium (Te), zinc (Zn), magnesium (Mg), germanium (Ge), aluminum (Al), rhodium (Rh), ruthenium (Ru), molybdenum (Mo), and silicon (Si).

10. The reflective mask according to claim 6, wherein
a distance from the center of the substrate to an outer peripheral end of the multilayer reflective film is denoted by Lml, and a distance from the center of the substrate to an outer peripheral end of the protective film is denoted by Lcap, and wherein Lml<Lcap, and
wherein a combined film thickness of the protective film and the absorber film is 4.5 nm or more in the area that is less than 2.5 nm near the at least one edge of the substrate.

11. The reflective mask according to claim 6, wherein the absorber film comprises at least one of tantalum (Ta), palladium (Pd), zirconium (Zr), hafnium (Hf), yttrium (Y), niobium (Nb), vanadium (V), titanium (Ti), lanthanum (La), and scandium (Sc).

12. The reflective mask according to claim 6, wherein the film thickness T nm of the absorber film at the center of the substrate is at least 30 nm.

13. The reflective mask according to claim 6, wherein the protective film comprises ruthenium (Ru).

14. The reflective mask according to claim 6, wherein the absorber film comprises at least one of silver (Ag), platinum (Pt), gold (Au), iridium (Ir), tungsten (W), chromium (Cr), cobalt (Co), manganese (Mn), tin (Sn), nickel (Ni), iron (Fe), copper (Cu), tellurium (Te), zinc (Zn), magnesium (Mg), germanium (Ge), aluminum (Al), rhodium (Rh), ruthenium (Ru), molybdenum (Mo), and silicon (Si).

15. The reflective mask blank according to claim 1, wherein the absorber film and protective film have a decreasing thickness toward the edge of substrate in the area that is less than 2.5 nm near the at least one edge of the substrate.

16. The reflective mask according to claim 6, wherein the absorber film and protective film have a decreasing thickness toward the edge of substrate in the area that is less than 2.5 nm near the at least one edge of the substrate.

17. The reflective mask blank according to claim 2, wherein the absorber film comprises at least one of tantalum (Ta), palladium (Pd), zirconium (Zr), hafnium (Hf), yttrium (Y), niobium (Nb), vanadium (V), titanium (Ti), lanthanum (La), and scandium (Sc).

18. The reflective mask blank according to claim 2, wherein the film thickness T nm of the absorber film at the center of the substrate is at least 30 nm.

19. The reflective mask blank according to claim 2, wherein the protective film comprises ruthenium (Ru).

20. The reflective mask blank according to claim 3, wherein the film thickness T nm of the absorber film at the center of the substrate is at least 30 nm.

21. The reflective mask blank according to claim 3, wherein the protective film comprises ruthenium (Ru).
